(19) United States
(12) Patent Application Publication
(10) Pub. No.: US 2021/0373809 A1
(43) Pub. Date: Dec. 2, 2021

(54) Write Data-Transfer Scheduling in ZNS Drive

(71) Applicant: Western Digital Technologies, Inc., San Jose, CA (US)

(72) Inventor: Shay BENISTY, Beer Sheva (IL)

(21) Appl. No.: 16/888,271

(22) Filed: May 29, 2020

(51) Int. Cl. G06F 3/06

(52) U.S. Cl. CPC G06F 3/0659; G06F 3/0653; G06F 3/0673; G06F 3/0613; G06F 3/0658

(57) ABSTRACT

The present disclosure generally relates to scheduling zone-append commands for a zoned namespace (ZNS). Rather than scheduling data transfer based on a zone-append command size, the data transfer scheduling is based upon memory device page chunks. Each zone-append command is first associated with a memory device die and queued in a relevant die queue. A data chuck that is the size of a page is fetched from a host device for each pending die. When fetching the chunk of data, a timer is activated and fetching of the next chunk of data for the specific die is allowed only once the timer expires. The value of the timer is set to be less than the time necessary to write a data chunk to the die.

### BACKGROUND OF THE DISCLOSURE

### Field of the Disclosure

Embodiments of the present disclosure generally relate to efficient data transfer management of zone-append commands for a zoned namespace (ZNS).

### Description of the Related Art

Zoned namespaces (ZNS) are a new direction in storage in which the data storage device restricts writes to sequential zones. ZNS is intended to reduce device side write amplification and overprovisioning by aligning host write patterns with internal device geometry and reducing the need for device side writes that are not directly linked to a host write.

ZNS offers many benefits including: reduced cost due to minimal DRAM requirements per SSD (Solid State Drive); potential savings due to decreased need for overprovisioning of NAND media; better SSD lifetime by reducing write amplification; dramatically reduced latency; significantly improved throughput; and a standardized interface that enables a strong software and hardware eco-system.

Typically, in a ZNS environment, the data transfer size associated with each zone-append command is a block size (e.g., a NAND block size) or multiple whole block sizes (i.e., no sizes of less than an entire block). A block, such as a NAND block for example, resides in a single NAND die. Memory device parallelism involves accessing multiple NAND dies in parallel. In order to increase parallelism, more NAND dies need to be accessed in parallel. In order to use the memory device parallelism efficiently, many zone-append commands should be executed in parallel while having interleaved data transfer. Otherwise, the write cache buffer will be increased significantly in order to utilize the memory device.

Therefore, there is a need in the art for a ZNS device with more efficient management of zone-append commands.

### SUMMARY OF THE DISCLOSURE

The present disclosure generally relates to scheduling zone-append commands for a zoned namespace (ZNS). Rather than scheduling data transfer based on a zone-append command size, the data transfer scheduling is based upon memory device page chunks. Each zone-append command is first associated with a memory device die and queued in a relevant die queue. A data chuck that is the size of a page is fetched from a host device for each pending die. When fetching the chunk of data, a timer is activated and fetching of the next chunk of data for the specific die is allowed only once the timer expires. The value of the timer is set to be less than the time necessary to write a data chunk to the die.

In one embodiment, a data storage device comprises: a memory device having a plurality of memory dies; and a controller coupled to the memory device, wherein the controller is configured to: receive a plurality of zone-append commands; fetch data from a host device for each zone-append command, wherein the fetched data for each zone-append command is less than all of the data associated with an individual zone-append command of the plurality of zone-append commands; and write the fetched data to the memory device.

In another embodiment, a data storage device comprises: a memory device including a plurality of dies; and a controller coupled to the memory device, wherein the controller is configured to: receive a first zone-append command associated with a first die of the plurality of dies; receive a second zone-append command associated with a second die of the plurality of dies; fetch a first chunk of first zone-append command data; fetch a first chunk of second zone-append command data; write the first chunk of first zone-append command data to the first die; write the first chunk of second zone-append command data to the second die; and fetch a second chunk of first zone-append command data, wherein the second chunk of first zone-append command data is fetched after a predetermined period of time; and wherein the predetermined period of time is less than a period of time necessary to write the first chunk of first zone data to the first die.

In another embodiment, a data storage device comprises: a memory device; a controller coupled to the memory device; and means to fetch data associated with a zone-append command, the means to fetch data associated with a zone-append command is coupled to the memory device, wherein the fetched data has a size equal to a page size of a die of the memory device, and wherein data associated with the zone-append command has a size greater than the page size of the die of the memory device.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic block diagram illustrating a storage system having a storage device that may function as a storage device for a host device, in accordance with one or more techniques of this disclosure.

FIG. 2A is a schematic illustration of device control of a traditional SSD.

FIG. 2B is a schematic illustration of device control of a ZNS SSD according to an embodiment.

FIG. 3 is a schematic illustration of a zone-append command.

FIG. 4 is a schematic illustration of a state diagram for a ZNS SSD according to one embodiment.

FIG. 5 is schematic illustration of a zone namespace structure according to one embodiment.

FIG. 6 is a schematic illustration of a ZNS non-interleaved data transfer.

FIG. 7 is schematic illustration of a ZNS interleaved and optimized data transfer according to one embodiment.

FIG. 8 is a schematic illustration of parsing zone-append commands according to one embodiment.

FIG. 9 is flowchart illustrating a method of interleaving and optimizing data transfer in a ZNS device according to one embodiment.

To facilitate understanding, identical reference numerals have been used, where possible, to designate identical elements that are common to the figures. It is contemplated that elements disclosed in one embodiment may be beneficially utilized on other embodiments without specific recitation.

### DETAILED DESCRIPTION

In the following, reference is made to embodiments of the disclosure. However, it should be understood that the disclosure is not limited to specific described embodiments. Instead, any combination of the following features and elements, whether related to different embodiments or not, is contemplated to implement and practice the disclosure. Furthermore, although embodiments of the disclosure may achieve advantages over other possible solutions and/or over the prior art, whether or not a particular advantage is achieved by a given embodiment is not limiting of the disclosure. Thus, the following aspects, features, embodiments and advantages are merely illustrative and are not considered elements or limitations of the appended claims except where explicitly recited in a claim(s). Likewise, reference to “the disclosure” shall not be construed as a generalization of any inventive subject matter disclosed herein and shall not be considered to be an element or limitation of the appended claims except where explicitly recited in a claim(s).

The present disclosure generally relates to scheduling zone-append commands for a zoned namespace (ZNS). Rather than scheduling data transfer based on a zone-append command size, the data transfer scheduling is based upon memory device page chunks. Each zone-append command is first associated with a memory device die and queued in a relevant die queue. A data chuck that is the size of a page is fetched from a host device for each pending die. When fetching the chunk of data, a timer is activated and fetching of the next chunk of data for the specific die is allowed only once the timer expires. The value of the timer is set to be less than the time necessary to write a data chunk to the die.

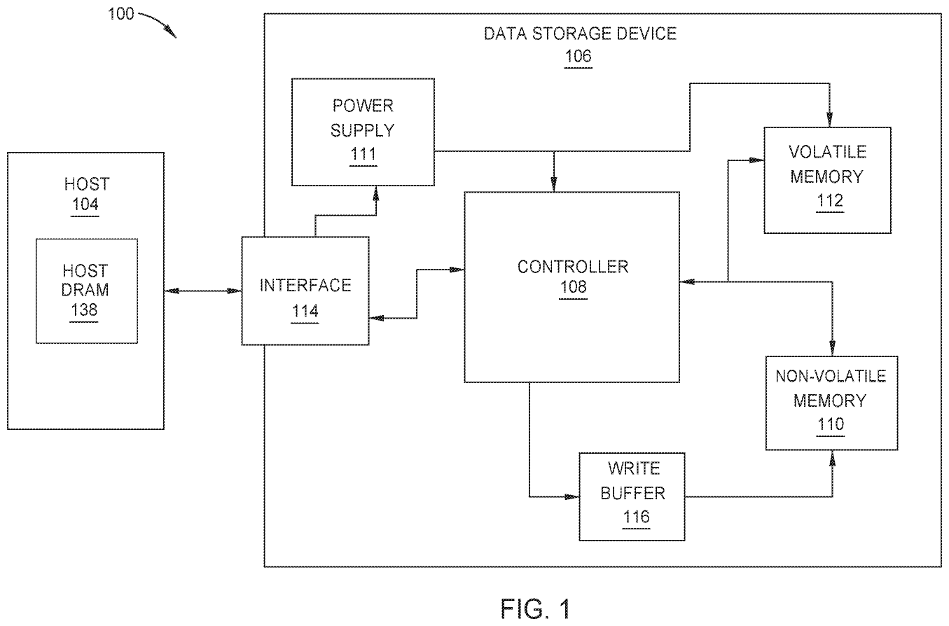

FIG. 1 is a schematic block diagram illustrating a storage system 100 in which data storage device 106 may function as a storage device for a host device 104, in accordance with one or more techniques of this disclosure. For instance, the host device 104 may utilize NVM 110 included in data storage device 106 to store and retrieve data. The host device 104 comprises a host DRAM 138. In some examples, the storage system 100 may include a plurality of storage devices, such as the data storage device 106, which may operate as a storage array. For instance, the storage system 100 may include a plurality of data storage devices 106 configured as a redundant array of inexpensive/independent disks (RAID) that collectively function as a mass storage device for the host device 104.

The storage system 100 includes a host device 104 which may store and/or retrieve data to and/or from one or more storage devices, such as the data storage device 106. As illustrated in FIG. 1, the host device 104 may communicate with the data storage device 106 via an interface 114. The host device 104 may comprise any of a wide range of devices, including computer servers, network attached storage (NAS) units, desktop computers, notebook (i.e., laptop) computers, tablet computers, set-top boxes, telephone handsets such as so-called “smart” phones, so-called “smart” pads, televisions, cameras, display devices, digital media players, video gaming consoles, video streaming device, and the like.

The data storage device 106 includes a controller 108, non-volatile memory 110 (NVM 110), a power supply 111, volatile memory 112, an interface 114, and a write buffer 116. In some examples, the data storage device 106 may include additional components not shown in FIG. 1 for sake of clarity. For example, the data storage device 106 may include a printed circuit board (PCB) to which components of the data storage device 106 are mechanically attached and which includes electrically conductive traces that electrically interconnect components of the data storage device 106, or the like. In some examples, the physical dimensions and connector configurations of the data storage device 106 may conform to one or more standard form factors. Some example standard form factors include, but are not limited to, 3.5″ data storage device (e.g., an HDD or SSD), 2.5″ data storage device, 1.8″ data storage device, peripheral component interconnect (PCI), PCI-extended (PCI-X), PCI Express (PCIe) (e.g., PCIe x1, x4, x8, x16, PCIe Mini Card, MiniPCl, etc.). In some examples, the data storage device 106 may be directly coupled (e.g., directly soldered) to a motherboard of the host device 104.

The interface 114 of the data storage device 106 may include one or both of a data bus for exchanging data with the host device 104 and a control bus for exchanging commands with the host device 104. The interface 114 may operate in accordance with any suitable protocol. For example, the interface 114 may operate in accordance with one or more of the following protocols: advanced technology attachment (ATA) (e.g., serial-ATA (SATA) and parallel-ATA (PATA)), Fibre Channel Protocol (FCP), small computer system interface (SCSI), serially attached SCSI (SAS), PCI, and PCIe, non-volatile memory express (NVMe), OpenCAPI, GenZ, Cache Coherent Interface Accelerator (CCIX), Open Channel SSD (OCSSD), or the like. The electrical connection of the interface 114 (e.g., the data bus, the control bus, or both) is electrically connected to the controller 108, providing electrical connection between the host device 104 and the controller 108, allowing data to be exchanged between the host device 104 and the controller 108. In some examples, the electrical connection of the interface 114 may also permit the data storage device 106 to receive power from the host device 104. For example, as illustrated in FIG. 1, the power supply 111 may receive power from the host device 104 via the interface 114.

The data storage device 106 includes NVM 110, which may include a plurality of memory devices or memory units. NVM 110 may be configured to store and/or retrieve data. For instance, a memory unit of NVM 110 may receive data and a message from the controller 108 that instructs the memory unit to store the data. Similarly, the memory unit of NVM 110 may receive a message from the controller 108 that instructs the memory unit to retrieve data. In some examples, each of the memory units may be referred to as a die. In some examples, a single physical chip may include a plurality of dies (i.e., a plurality of memory units). In some examples, each memory unit may be configured to store relatively large amounts of data (e.g., 128 MB, 256 MB, 512 MB, 1 GB, 2 GB, 4 GB, 8 GB, 16 GB, 32 GB, 64 GB, 128 GB, 256 GB, 512 GB, 1 TB, etc.).

In some examples, each memory unit of NVM 110 may include any type of non-volatile memory devices, such as flash memory devices, phase-change memory (PCM) devices, resistive random-access memory (ReRAM) devices, magnetoresistive random-access memory (MRAM) devices, ferroelectric random-access memory (F-RAM), holographic memory devices, and any other type of non-volatile memory devices.

The NVM 110 may comprise a plurality of flash memory devices or memory units. Flash memory devices may include NAND or NOR based flash memory devices, and may store data based on a charge contained in a floating gate of a transistor for each flash memory cell. In NAND flash memory devices, the flash memory device may be divided into a plurality of blocks which may be divided into a plurality of pages. Each block of the plurality of blocks within a particular memory device may include a plurality of NAND cells. Rows of NAND cells may be electrically connected using a word line to define a page of a plurality of pages. Respective cells in each of the plurality of pages may be electrically connected to respective bit lines. Furthermore, NAND flash memory devices may be 2D or 3D devices, and may be single level cell (SLC), multi-level cell (MLC), triple level cell (TLC), or quad level cell (QLC). The controller 108 may write data to and read data from NAND flash memory devices at the page level and erase data from NAND flash memory devices at the block level.

The data storage device 106 includes a power supply 111, which may provide power to one or more components of the data storage device 106. When operating in a standard mode, the power supply 111 may provide power to the one or more components using power provided by an external device, such as the host device 104. For instance, the power supply 111 may provide power to the one or more components using power received from the host device 104 via the interface 114. In some examples, the power supply 111 may include one or more power storage components configured to provide power to the one or more components when operating in a shutdown mode, such as where power ceases to be received from the external device. In this way, the power supply 111 may function as an onboard backup power source. Some examples of the one or more power storage components include, but are not limited to, capacitors, super capacitors, batteries, and the like. In some examples, the amount of power that may be stored by the one or more power storage components may be a function of the cost and/or the size (e.g., area/volume) of the one or more power storage components. In other words, as the amount of power stored by the one or more power storage components increases, the cost and/or the size of the one or more power storage components also increases.

The data storage device 106 also includes volatile memory 112, which may be used by controller 108 to store information. Volatile memory 112 may be comprised of one or more volatile memory devices. In some examples, the controller 108 may use volatile memory 112 as a cache. For instance, the controller 108 may store cached information in volatile memory 112 until cached information is written to non-volatile memory 110. As illustrated in FIG. 1, volatile memory 112 may consume power received from the power supply 111. Examples of volatile memory 112 include, but are not limited to, random-access memory (RAM), dynamic random access memory (DRAM), static RAM (SRAM), and synchronous dynamic RAM (SDRAM (e.g., DDR1, DDR2, DDR3, DDR3L, LPDDR3, DDR4, LPDDR4, and the like)).

The data storage device 106 includes a controller 108, which may manage one or more operations of the data storage device 106. For instance, the controller 108 may manage the reading of data from and/or the writing of data to the NVM 110. In some embodiments, when the data storage device 106 receives a write command from the host device 104, the controller 108 may initiate a data storage command to store data to the NVM 110 and monitor the progress of the data storage command. The controller 108 may determine at least one operational characteristic of the storage system 100 and store the at least one operational characteristic to the NVM 110. In some embodiments, when the data storage device 106 receives a write command from the host device 104, the controller 108 temporarily stores the data associated with the write command in the internal memory or write buffer 116 before sending the data to the NVM 110.

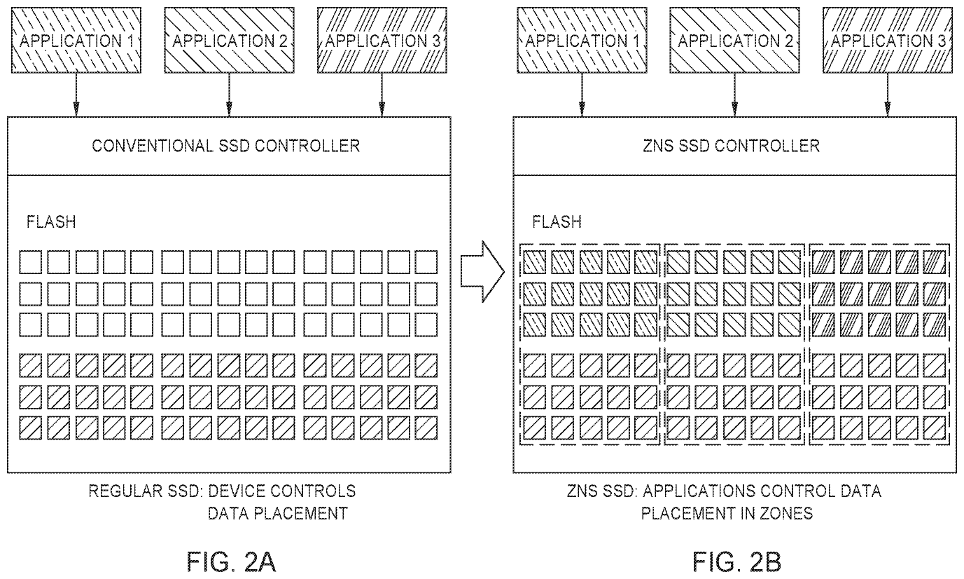

FIGS. 2A and 2B are schematic illustrations of device control of a SSD, according to various embodiments. In one embodiment, the flash device of FIG. 2A and FIG. 2B may be the NVM 110 of the data storage device 106 of FIG. 1. Furthermore, according to various embodiments, the flash device of FIG. 2A and FIG. 2B may be a multi-level cell, such as SLC, MLC, TLC, QLC, or any other iteration of multi-level cell not listed. Each square of the block storage device of FIG. 2A and FIG. 2B represents a block available for data storage. A shaded square or block denotes that the block comprises data. The data may be user data, XOR or parity data, device metadata, or any other suitable data to be stored in the flash of the SSD.

FIG. 2A is a schematic illustration of device control of a traditional SSD. The SSD receives data from multiple applications, such as Application 1, Application 2, and Application 3. The data is stored in the flash of the SSD. In the SSD, the storage device controls the data placement. Data is written sequentially to the flash so that the data from each application may be written in the order that the data is received. Because the data from each application may be random throughout the sequential writes, the latency may be increased and the throughput may be hindered.

FIG. 2B is a schematic illustration of device control of a ZNS SSD. Similar to FIG. 2A, the SSD receives data from multiple applications, such as Application 1, Application 2, and Application 3. The data is stored in the flash of the SSD. In the SSD, the applications or the host, such as the host device 104 of FIG. 1, controls the data placement in the zones. The flash of the SSD is partitioned into various equal capacity zones. The zones may be considered parallel units, in which the host device 104 may direct workloads or data to a specific parallel unit (i.e., the host has block access of the flash). For example, the data associated with Application 1 is located in a first zone, while the data associated with Application 2 is located in a second zone and the data associated with Application 3 is located in a third zone. Due to the zone provisioning, the latency is reduced from the latency of the traditional SSD device control and the throughput is improved from the throughput of the traditional SSD device control.

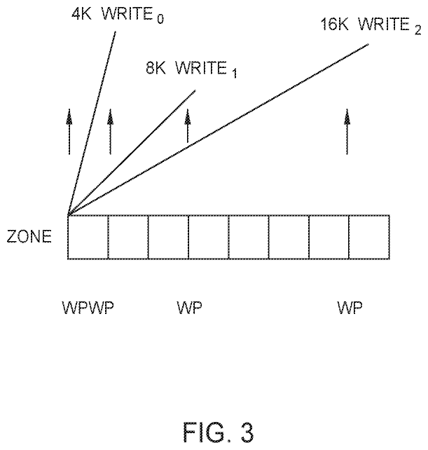

FIG. 3 is a schematic illustration of a zone-append command. The host, such as the host device 104 of FIG. 1, opens the zone implicitly or explicitly. The host device 104 issues several zone-append commands to the same address. Storage device, such as the data storage device 106 of FIG. 1, is responsible for populating the data from the host device 104 and notifying the host device 104 where exactly the data is written within the zone for each command. The location of the data written to the NVM, such as the NVM 110 of FIG. 1, is stored within a logical to physical (L2P) table in the volatile memory, such as the volatile memory 112 of FIG. 1, and the NVM 110. The L2P table comprises pointers to one or more logical block addresses (LBAs) storing data, such as user data.

As illustrated in FIG. 3, each block in the zone is a 4 K size. The term “block” is utilized for exemplary purposes and is not constrained to a 4 K size. Three write commands (i.e., three zone-append commands) are received by the data storage device 106 in the order of a 4 K Write₀, an 8 K Write₁, and a 16 K Write₂. Furthermore, a write pointer (WP) of a zone corresponds to the next available location for a write command. In FIG. 3, the 4 K Write₀ is written to the first block and the new write pointer location is at the start of the second block (i.e., at the 4 K size location in the zone). After the Write₀ is written to the first block, the 8 K Write₁ is written to the next available blocks, occupying the next two blocks (i.e., two 4 K size blocks). The write pointer is updated to reflect the 16 K size location of the zone for the next write command. The last 16 K Write₂ command is written to the next four blocks (i.e., four 4 K size blocks). The write pointer is updated to reflect a total zone size of 28 K, where the next write command will be written to the 28 K size location. At each location, the host is updated with the exact location of the written data in the zone via a completion message associated with each zone append command. Though exemplified in the order above, the write commands received at the same time may be written sequentially in any order (i.e., out of order), such that Write₂ may be written prior to Write₀, in the zone due to the ZNS environment.

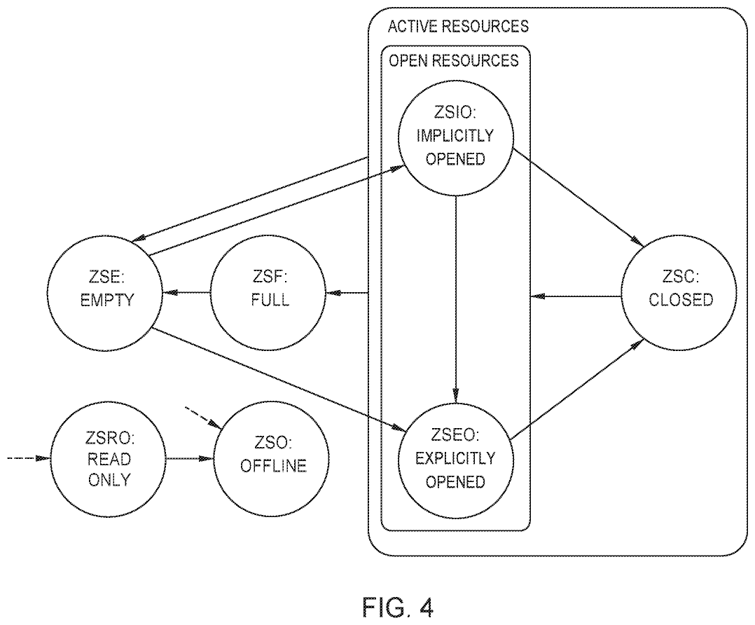

FIG. 4 is a schematic illustration of a state diagram for a ZNS SSD according to one embodiment. In FIG. 4, the various zone states (ZS) are empty (i.e., ZSE:Empty), implicitly opened (i.e., ZSIO:Implicitly Opened), explicitly opened (i.e., ZSEO:Explicitly Opened), closed (i.e., ZSC:Closed), full (i.e., ZSF:Full), read only (i.e., ZSRO:Read Only), and offline (i.e., ZSO:Offline). A generic flow path for a zone may be from an empty state to an open state, which may be either implicitly opened or explicitly opened. From an open state, the zone may be at capacity so that the ZNS is full. After the full state, the zone contents may be erased, which resets the ZNS to empty.

The initial state for each zone after a controller, such as the controller 108 of FIG. 1, power-on or reset event is determined by the zone characteristics of each zone. For example, the zone state, ZSE:Empty, is denoted by a valid write pointer (WP) that points to the lowest LBA (i.e., zone start LBA) in the zone. The zone state, ZSC:Closed, is denote by a WP that does not point to the lowest LBA in the zone. The zone state, ZSF:Full, is the initial state if the most recent zone condition was full. The zone state, ZSRO:Read Only, is the initial state if the most recent zone condition was read only. The zone state, ZSO:Offline, is the initial state if the most recent zone condition was offline.

The zones may have any total capacity or total size, such as 256 MiB or 512 MiB. However, a small portion of each zone may be inaccessible to write data to, but may still be read, such as a portion of each zone storing the XOR data, metadata, and one or more excluded erase blocks. For example, if the total capacity of a zone is 512 MiB, the zone capacity (ZCAP) may be 470 MiB, which is the capacity available to write data to, while 42 MiB are unavailable to write data. The ZCAP of a zone is equal to or less than the total zone storage capacity or total zone storage size. The storage device, such as the data storage device 106 of FIG. 1 or the SSD of FIG. 2B, may determine the ZCAP of each zone upon zone reset. For example, the controller, such as the controller 108 of FIG. 1, may determine the ZCAP of each zone. The storage device may determine the ZCAP of a zone when the zone is reset.

When a zone is empty (i.e., ZSE:Empty), the zone is free of data (i.e., none of the erase blocks in the zone are currently storing data) and the write pointer (WP) is at the zone start LBA (ZSLBA) (i.e., WP=0). The ZSLBA refers to the start of a zone (i.e., the first NAND location of a zone). The write pointer signifies the location of the data write in a zone of the storage device. An empty zone switches to an open and active zone once a write is scheduled to the zone or if the zone open command is issued by the host (i.e., ZSIO:Implicitly Opened or ZSEO:Explicitly Opened). Zone management (ZM) commands can be used to move a zone between zone open and zone closed states, which are both active states. If a zone is active, the zone comprises open blocks that may be written to, and the host may be provided a description of recommended time in the active state. The controller 108 comprises the ZM (not shown). Zone metadata may be stored in the ZM and/or the controller 108.

The term “written to” includes programming user data on 0 or more NAND locations in an erase block and/or partially filled NAND locations in an erase block when user data has not filled all of the available NAND locations. A NAND location may be a flash location, as referred to in FIGS. 2A and 2B. The term “written to” may further include moving a zone to full (i.e., ZSF:Full) due to internal drive handling needs (open block data retention concerns because the bits in error accumulate more quickly on open erase blocks), the data storage device 106 closing or filling a zone due to resource constraints, like too many open zones to track or discovered defect state, among others, or a host device, such as the host device 104 of FIG. 1, closing the zone for concerns such as there being no more data to send the drive, computer shutdown, error handling on the host, limited host resources for tracking, among others.

The active zones may be either open (i.e., ZSIO:Implicitly Opened or ZSEO:Explicitly Opened) or closed (i.e., ZSC:Closed). An open zone is an empty or partially full zone that is ready to be written to and has resources currently allocated. The data received from the host device with a write command or zone-append command may be programmed to an open erase block that is not currently filled with prior data. A closed zone is an empty or partially full zone that is not currently receiving writes from the host in an ongoing basis. The movement of a zone from an open state to a closed state allows the controller 108 to reallocate resources to other tasks. These tasks may include, but are not limited to, other zones that are open, other conventional non-zone regions, or other controller needs.

In both the open and closed zones, the write pointer is pointing to a place in the zone somewhere between the ZSLBA and the end of the last LBA of the zone (i.e., WP>0). Active zones may switch between the open and closed states per designation by the ZM, or if a write is scheduled to the zone. Additionally, the ZM may reset an active zone to clear or erase the data stored in the zone such that the zone switches back to an empty zone. Once an active zone is full, the zone switches to the full state. A full zone is one that is completely filled with data, and has no more available blocks to write data to (i.e., WP=zone capacity (ZCAP)). In a full zone, the write pointer points to the end of the writeable capacity of the zone. Read commands of data stored in full zones may still be executed.

The ZM may reset a full zone (i.e., ZSF:Full), scheduling an erasure of the data stored in the zone such that the zone switches back to an empty zone (i.e., ZSE:Empty). When a full zone is reset, the zone may not be immediately cleared of data, though the zone may be marked as an empty zone ready to be written to. However, the reset zone must be erased prior to switching to an open and active zone. A zone may be erased any time between a ZM reset and a ZM open. Upon resetting a zone, the data storage device 106 may determine a new ZCAP of the reset zone and update the Writeable ZCAP attribute in the zone metadata. An offline zone is a zone that is unavailable to write data to. An offline zone may be in the full state, the empty state, or in a partially full state without being active.

Since resetting a zone clears or schedules an erasure of all data stored in the zone, the need for garbage collection of individual erase blocks is eliminated, improving the overall garbage collection process of the data storage device 106. The data storage device 106 may mark one or more erase blocks for erasure. When a new zone is going to be formed and the data storage device 106 anticipates a ZM open, the one or more erase blocks marked for erasure may then be erased. The data storage device 106 may further decide and create the physical backing of the zone upon erase of the erase blocks. Thus, once the new zone is opened and erase blocks are being selected to form the zone, the erase blocks will have been erased. Moreover, each time a zone is reset, a new order for the LBAs and the write pointer for the zone may be selected, enabling the zone to be tolerant to receive commands out of sequential order. The write pointer may optionally be turned off such that a command may be written to whatever starting LBA is indicated for the command.

The controller 108 provides a T_{ZoneActiveLimit} (ZAL) value per zone. The ZAL may also be applicable to blocks and/or streams, in various embodiments. Each zone is assigned a ZAL value, which the ZAL value represents the time that the open zone may remain open. In standard storage devices, the ZAL value is fixed throughout the time that the relevant zone is in usage by the host device 104 (i.e., the storage device receives write or read commands from the host for the relevant zone). The ZAL value is shared by each zone of the namespace (i.e., a global ZAL value). The time that that ZAL value corresponds to is a maximum value of time before an unacceptable amount of bit errors have accumulated in a zone. The host device 104 or the data storage device 106 may close the zone prior to reaching the ZAL value to avoid the unacceptable amount of bit errors accumulated.

If the zone active limit is a non-zero value, the controller may transition a zone in either ZSIO:Implicitly Opened, ZSEO:Explicitly Opened or ZSC:Closed state to the ZSF:Full state. When a zone is transitioned to the ZSIO:Implicitly Opened state or ZSEO:Explicitly Opened state, an internal timer in seconds starts so that the host device 104 or the data storage device 106 recognizes when the ZAL value is exceeded. If the ZAL value or time limit is exceeded, the controller 108 may either warn the host device 104 that the zone requires finishing (i.e., the zone needs to be at capacity) or transition the zone to the ZSF:Full state. When the host device 104 is warned that the zone requires finishing, the zone finish recommended field is set to 1 and the zone information changed event is reported to the host device 104. When the zone is transitioned to the ZSF:Full state, the zone finished by controller field is set to 1 and the zone information changed event is reported to the host device 104. Because the ZAL value is a global parameter for each zone of the storage device, a zone may be closed prematurely allowing for less than optimal storage drive operation or be closed late allowing for an unacceptable amount of bit errors to accumulate, which may result in a decreased integrity of the data storage device. The unacceptable accumulation of bit errors may also result in a decreased performance of the data storage device. The global ZAL parameter is a static parameter and may be based on a worst-case estimate of the conditions that a host may face.

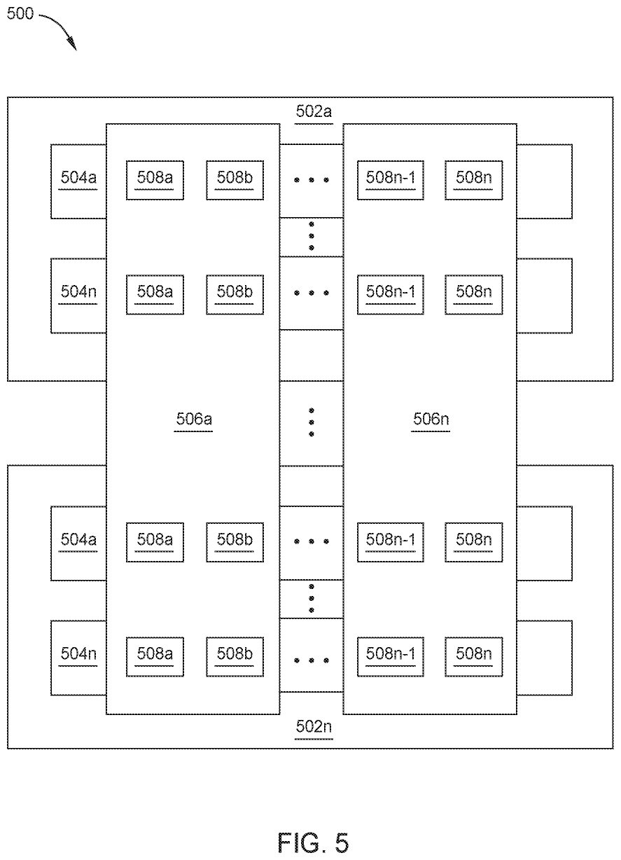

FIG. 5 is schematic illustration of a zone namespace structure 500 according to one embodiment. The zone namespace structure 500 includes a plurality of NAND channels 502a-502n, where each NAND channel 502a-502n includes one or more dies 504a-504n. Each NAND channel 502a-502n may have a dedicated hardware (HW) interface, such that each NAND channel 502a-502n is independent from another NAND channel 502a-502n. Each of the one or more dies 504a-504n includes one or more erase blocks 508a-508n. The zone namespace structure 500 further includes one or more zones 506a-506n, where each zone 506a-506n includes one or more erase blocks 508a-508n from each of the plurality of dies. In one embodiment, the size of each of the plurality of zones are equal. In another embodiment, the size of each of the plurality of zones are not equal. In yet another embodiment, the size of one or more zones are equal and the size of the remaining one or more zones are not equal.

For example, a first zone 506a includes the first erase block 508a and the second erase block 508b from each die 504a-504n of each NAND channel 502a-502n. A zone 506a-506n may include two erase blocks 508a-508n from each die 504a-504n, such that two erase blocks 508a-508n increases parallelism when reading or writing data to the die 504a-504n and/or zone 506a-506n. In one embodiment, a zone may include an even number of erase blocks from each die. In another embodiment, a zone may include an odd number of erase blocks from each die. In yet another embodiment, a zone may include one or more erase blocks from one or more dies, where the one or more erase blocks may not be chosen from one or more dies.

Furthermore, the data transfer size associated with each zone-append command to a zone 506a-506n may be in the size of an erase block to take advantage of NAND parallelism and to optimize the zone-append command to NAND features. If the data transfer size (e.g., write size) associated with a zone-append command is less than the minimum transfer size (e.g., write size), such as the size of an erase block, the zone-append command may be held at a buffer, such as a write buffer 116 of FIG. 1, until the one or more zone-append commands held at the buffer aggregate to the minimum transfer size. When executing the one or more zone-append commands in parallel, the data transfer is interleaved with each zone-append command in order to minimize the size of the write cache buffer (e.g. the write buffer 116).

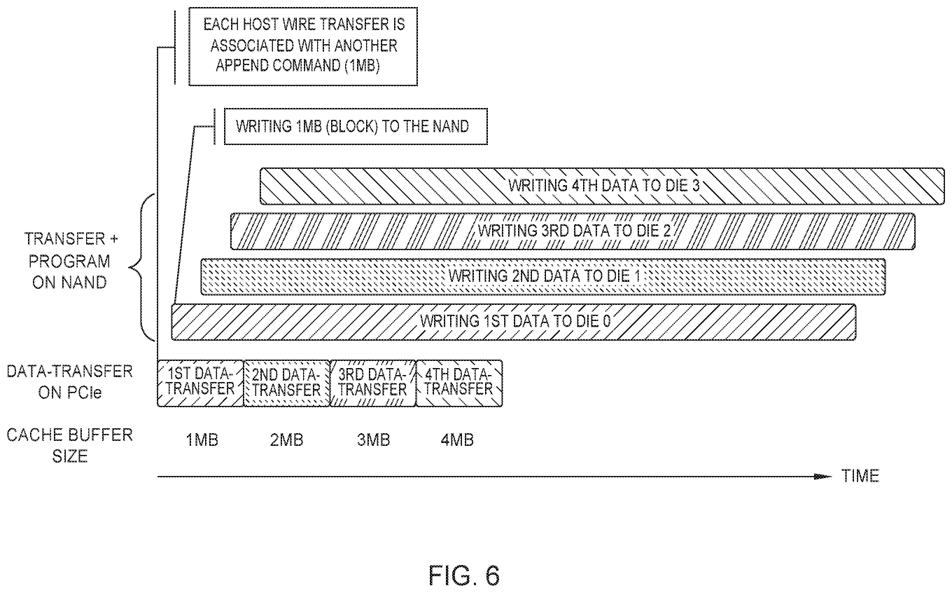

FIG. 6 is a schematic illustration of a ZNS non-interleaved data transfer. The ZNS non-interleaved data transfer is illustrated as the data transfer over a period of time. In FIG. 6, four zone-append commands are sent to the storage device to be written to a zone. The size of the data associated with each of the four zone-append commands is 1 MB. For example, the size of the data associated with the first zone-append command is 1 MB, the size of the data associated with the second zone-append command is 1 MB, and so-forth.

The data for each of the zone-append commands are transferred over a data bus, such as a PCIe bus, where a controller, such as the controller 108 of FIG. 1, queues the zone-append commands to be written to the respective location in the die of the respective zone. The transfer of 1 MB of first data for the first zone-append command over the data bus may take about 0.14 mSec. The listed time value is not intended to be limiting, but to provide an example of an embodiment. After the transfer of the first data for the first zone-append command has completed, the second data associated with the second zone-append command can be transferred, and likewise for the third data for the third zone-append command and so-forth.

After the data for a zone-append command is transferred over the data bus, the data is transferred and programmed to the NAND interface. The program of the data to the NAND interface occurs over a NAND page granularity, such as about 32 KB, about 64 KB, about 96 KB or any other appropriate size not listed. Each data program operation may take about 2 mSec, where writing 1 MB of data may take about 20 mSec. Consider, for example, that the time to write 1 MB of data is much greater than the time to fetch the data to be written (i.e., 0.14 mSec). Prior to writing, all fetched data is cached internally. As the time to fetch data is much less than the time to write data, a large amount of data will be cached, necessitating a very large cache size. In order to start the execution of the next command in parallel to the previously fetched command, the cache will be sufficiently large to ensure the cache will not become full when all data associated with the first fetched command is cached. If the cache is not full, then the second command can be fetched and programmed to a different die in parallel. Due to the very large time difference between fetching and writing, a very large internal cache would be necessary to program different dies in parallel.

In FIG. 6, the controller receives four zone-append commands each to a different die. For example, the first zone-append command is for the first data to the first die0, the second zone-append command is for the second data to the second die1, the third zone-append command is for the third data to the third die2, and the fourth zone-append command is for the fourth data to the fourth die3. In the current embodiment, the controller has four available write buffers, such that after receiving the data associated with the four zone-append commands, each command can be executed. If a fifth zone-append command associated with a fifth data is received, the fifth zone-append command is queued in the controller buffer (e.g., write cache buffer) until a write buffer is freed. However, since the data size for each zone-append command is 1 MB, many zone-append commands may be stored in the controller buffer, thus increasing the size required for the write cache buffer. The additional size of the write cache buffer increases cost and requires more power for operation.

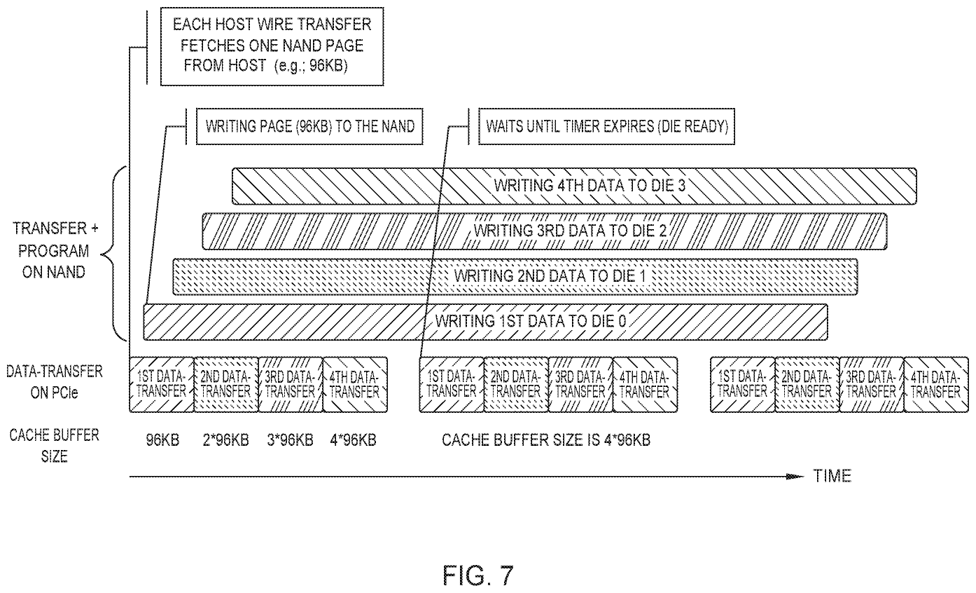

FIG. 7 is schematic illustration of a ZNS interleaved and optimized data transfer according to one embodiment. The ZNS interleaved and optimized data transfer illustrates the data transfer over a period of time. In FIG. 7, four zone-append commands are sent to the storage device to be written to a zone. The size of the data associated with each of the four zone-append commands is 1 MB. For example, the size of the data associated with the first zone-append command is 1 MB, the size of the data associated with the second zone-append command is 1 MB, and so-forth. However, the data associated with each of the four zone-append commands are partitioned into smaller sizes, such as a NAND page size of 96 KB. The listed size is not intended to be limiting, but to provide an example of an embodiment. Because the data is partitioned into a size of 96 KB, the cache buffer size (assuming four available buffers) is 4*96 KB=384 KB. However, if the data was not partitioned into the smaller data chunks, the total size of the cache buffer is 4 MB or 4,096 KB.

Each 96 KB data chunk is fetched from the host for each pending die, where a pending die is associated with a zone-append command. When fetching a chunk of data, such as a 96 KB data chunk associated with a first zone-append command, a timer is activated. The timer counts down from a predetermined value, such that when the timer expires, the next chunk of data for the same zone-append command can be fetched.

For example, a first data for a first zone-append command has a first timer, a second data for a second zone-append command has a second timer, a third data for a third zone-append command has a third timer, and a fourth data for fourth zone-append command has a fourth timer. The next 96 KB data chunk from the commands associated with the same die can only be fetched after the timer associated with the die expires. For example, when the timer expires for the first 96 KB data chunk for the first zone-append command, the second 96 KB data chunk for the first zone-append command can be fetched and programmed to die0. Because the data transfer sizes are programmed in smaller sections, a high performance and NAND utilization may be achieved without increasing the write cache buffer size within the storage device.

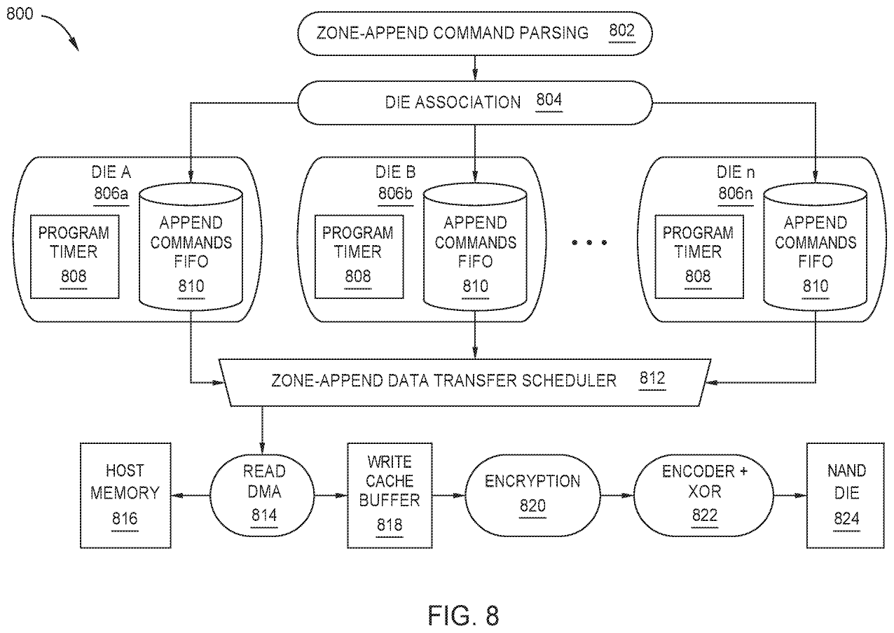

FIG. 8 is a schematic illustration of a block diagram of parsing zone-append commands 800 according to one embodiment. The block diagram of parsing zone-append commands 800 includes a zone-append command parsing 802, a die association 804, one or more dies 806a-806n, and a data transfer scheduler 812.

The zone-append command parsing 802 may partition the data associated with the zone-append command into smaller data chunks, such as in the description of FIG. 7. The controller, such as the controller 108 of FIG. 1, may include the die association 804, where the controller writes the data to the respective die 806a-806n. For example, if a first zone-append command for a first die and a second zone-append command for a second die are received, the controller die association 804 appropriates the portioned data to each respective die.

The one or more dies 806a-806n each have a program timer 808 and an append commands FIFO 810. When a first data chunk is written to a first die 806a, the program timer 808 for that first die 806a starts counting down. In one embodiment, the timer is initialized to about 2.2 mSec, which may be a NAND program time. When the program timer 808 expires, the next data chunk in the append commands FIFO 810 queue, such as the second data chunk for the first die 806a, can be written to the same die, such as the first die 806a. During this time, the storage device has enough time to program the data to the NAND die, such that the next data chunk would be available in the internal cache buffer when the data is being programmed to the NAND die. The zone-append data transfer scheduler 812 utilizes a round robin scheme to write data to each NAND die. However, the round robin scheme applies to the data chunks that that have pending zone-append commands in the queue and a program timer value of 0.

After the data chunk passes through the zone-append data transfer scheduler 812, the data chunk passes to the read DMA 814. The data may be transferred to the host memory 816 after the read DMA 814 or to the write cache buffer 818. When the data passes through the write cache buffer 818, the data chunk passes through an encryption engine 820 and an encoder and XOR generator 822 before being written to the relevant NAND die 824.

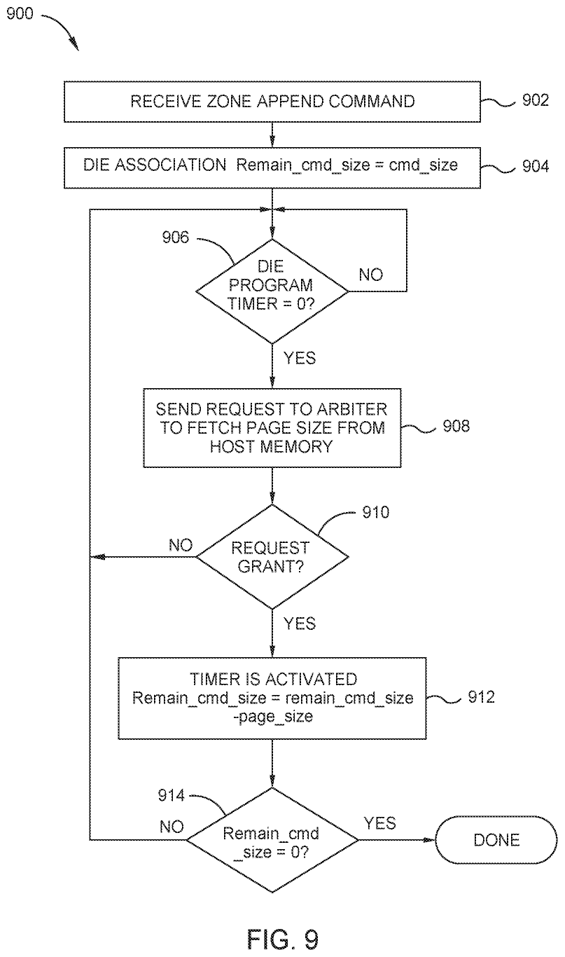

FIG. 9 is flowchart illustrating a method 900 of interleaving and optimizing data transfer in a ZNS device according to one embodiment. At block 902, the storage device receives a zone-append command. The storage device associates the zone-append command with the relevant die and queues the zone-append command to the relevant die queue at block 904. At block 906, the controller determines if the die program timer value is 0, where the die program timer value of 0 corresponds with an expired timer. If the die program timer does not equal 0, then the zone-append command remains in the die queue.

However, if the die program timer is 0, then the controller sends a request to arbiter to fetch page size from the host memory at block 908. After the request is granted at block 910, a timer is activated where the controller determines the remaining size of the data associated with the zone-append command that has not been fetched from the host memory at block 912. However, if the request is not granted at block 910, the method 900 restarts at block 906 with the remaining data. At block 914, if the size of the data associated with the zone-append command is 0, then the method 900 is completed. However, if the size of the data associated with the zone-append command is not 0, the method 900 restarts at block 906 with the remaining data.

By interleaving data transfer of zone-append commands in data chunks equivalent to a page size rather than a whole block, high performance memory device utilization is achieved without increasing write cache buffer size.

In one embodiment, a data storage device comprises: a memory device having a plurality of memory dies; and a controller coupled to the memory device, wherein the controller is configured to: receive a plurality of zone-append commands; fetch data from a host device for each zone-append command, wherein the fetched data for each zone-append command is less than all of the data associated with an individual zone-append command of the plurality of zone-append commands; and write the fetched data to the memory device. The fetched data for each zone-append command is a chunk of data having a size equal to a page. The controller is further configured to fetch additional data from the host device for each zone-append command and write the additional data to the memory device. Fetching additional data for each zone-append command occurs about 5 microseconds prior to completion of writing the fetched data for each zone-append command. The controller is further configured to activate a timer upon fetching data from the host device for each zone-append command. Each zone-append command is associated with a distinct die of the plurality of dies. Additional data of a zone-append command associated with a particular die of the plurality of dies is fetched about 5 microseconds prior to completion of writing the originally fetched data to the particular die. The controller is further configured to activate a timer for each die of the plurality of dies for which data is fetched.

In another embodiment, a data storage device comprises: a memory device including a plurality of dies; and a controller coupled to the memory device, wherein the controller is configured to: receive a first zone-append command associated with a first die of the plurality of dies; receive a second zone-append command associated with a second die of the plurality of dies; fetch a first chunk of first zone-append command data; fetch a first chunk of second zone-append command data; write the first chunk of first zone-append command data to the first die; write the first chunk of second zone-append command data to the second die; and fetch a second chunk of first zone-append command data, wherein the second chunk of first zone-append command data is fetched after a predetermined period of time; and wherein the predetermined period of time is less than a period of time necessary to write the first chunk of first zone data to the first die. The controller is further configured to activate a timer associated with the first die upon fetching the first chunk of first zone-append command data, wherein the timer is configured to run for the predetermined period of time. The first chunk of first zone-append command data has a size equal to a page size of the first die. The data storage device further comprises a write buffer, wherein the write buffer is configured to store data for the plurality of dies. The write buffer is configured to store data of a size equivalent to a value of a page of data for each die of the plurality of dies. The controller is configured to fetch the first chunk of first zone-append command data and to fetch the first chunk of second zone-append command data sequentially. The controller is configured to fetch the second chunk of first zone-append command data after fetching the first chunk of second zone-append command data.

In another embodiment, a data storage device comprises: a memory device; a controller coupled to the memory device; and means to fetch data associated with a zone-append command, the means to fetch data associated with a zone-append command is coupled to the memory device, wherein the fetched data has a size equal to a page size of a die of the memory device, and wherein data associated with the zone-append command has a size greater than the page size of the die of the memory device. The data storage device further comprises timing means, wherein the timing means is coupled to the memory device. The data storage device further comprises means to wait to fetch additional data associated with the zone-append command, wherein the means to wait is coupled to the memory device. The data storage device further comprises a write buffer coupled between the memory device and the controller. The write buffer is sized to store data equivalent in size to one page size for each die of the memory device.

While the foregoing is directed to embodiments of the present disclosure, other and further embodiments of the disclosure may be devised without departing from the basic scope thereof, and the scope thereof is determined by the claims that follow.

What is claimed is:

1. A data storage device, comprising:
a memory device having a plurality of memory dies; and
a controller coupled to the memory device, wherein the controller is configured to:
receive a plurality of zone-append commands;
fetch data from a host device for each zone-append command, wherein the fetched data for each zone-append command is less than all of the data associated with an individual zone-append command of the plurality of zone-append commands; and
write the fetched data to the memory device.

2. The data storage device of claim 1, wherein the fetched data for each zone-append command is a chunk of data having a size equal to a page.

3. The data storage device of claim 1, wherein the controller is further configured to fetch additional data from the host device for each zone-append command and write the additional data to the memory device.

4. The data storage device of claim 3, wherein fetching additional data for each zone-append command occurs about 5 microseconds prior to completion of writing the fetched data for each zone-append command.

5. The data storage device of claim 1, wherein the controller is further configured to activate a timer upon fetching data from the host device for each zone-append command.

6. The data storage device of claim 1, wherein each zone-append command is associated with a distinct die of the plurality of dies.

7. The data storage device of claim 6, wherein additional data of a zone-append command associated with a particular die of the plurality of dies is fetched about 5 microseconds prior to completion of writing the originally fetched data to the particular die.

8. The data storage device of claim 7, wherein the controller is further configured to activate a timer for each die of the plurality of dies for which data is fetched.

9. A data storage device, comprising:
a memory device including a plurality of dies; and
a controller coupled to the memory device, wherein the controller is configured to:
receive a first zone-append command associated with a first die of the plurality of dies;
receive a second zone-append command associated with a second die of the plurality of dies;
fetch a first chunk of first zone-append command data;
fetch a first chunk of second zone-append command data;
write the first chunk of first zone-append command data to the first die;
write the first chunk of second zone-append command data to the second die; and
fetch a second chunk of first zone-append command data, wherein the second chunk of first zone-append command data is fetched after a predetermined period of time; and wherein the predetermined period of time is less than a period of time necessary to write the first chunk of first zone data to the first die.

10. The data storage device of claim 9, wherein the controller is further configured to activate a timer associated with the first die upon fetching the first chunk of first zone-append command data, wherein the timer is configured to run for the predetermined period of time.

11. The data storage device of claim 9, wherein the first chunk of first zone-append command data has a size equal to a page size of the first die.

12. The data storage device of claim 9, further comprising a write buffer, wherein the write buffer is configured to store data for the plurality of dies.

13. The data storage device of claim 12, wherein the write buffer is configured to store data of a size equivalent to a value of a page of data for each die of the plurality of dies.

14. The data storage device of claim 9, wherein the controller is configured to fetch the first chunk of first zone-append command data and to fetch the first chunk of second zone-append command data sequentially.

15. The data storage device of claim 14, wherein the controller is configured to fetch the second chunk of first zone-append command data after fetching the first chunk of second zone-append command data.

16. A data storage device, comprising:
a memory device;
a controller coupled to the memory device; and
means to fetch data associated with a zone-append command, the means to fetch data associated with a zone-append command is coupled to the memory device, wherein the fetched data has a size equal to a page size of a die of the memory device, and wherein data associated with the zone-append command has a size greater than the page size of the die of the memory device.

17. The data storage device of claim 16, further comprising timing means, wherein the timing means is coupled to the memory device.

18. The data storage device of claim 16, further comprising means to wait to fetch additional data associated with the zone-append command, wherein the means to wait is coupled to the memory device.

19. The data storage device of claim 16, further comprising a write buffer coupled between the memory device and the controller.

20. The data storage device of claim 19, wherein the write buffer is sized to store data equivalent in size to one page size for each die of the memory device.
